(19) United States
(12) Patent Application Publication
(10) Pub. No.: US 2004/0267689 A1
(43) Pub. Date: Dec. 30, 2004

(54) Change management system

(75) Inventors: Michael A. Gavlak, Buffalo, NY (US); Michael D. Marra, Commerce Twp., MI (US); Lori H. Runk, North Tonawanda, NY (US)

Correspondence Address: RADER, FISHMAN & GRAUER PLLC, 39533 WOODWARD AVENUE, SUITE 140, BLOOMFIELD HILLS, MI, 48304-0610, US

(73) Assignee: Delphi Technologies Inc., Troy, MI

(21) Appl. No.: 10/606,989

(22) Filed: Jun. 26, 2003

(51) Int. Cl. G06F 7/00

(52) U.S. Cl. 707/1

(57) ABSTRACT

A system and method for managing changes to items associated with a complex system of inter-related items. The inventive system includes a database having a plurality of records, wherein each record includes information concerning an item associated with the assembled end product. The information contained in each record includes an identification of other items that could be affected by a change to the item associated with the record. The system further includes a computer-user interface displaying a user-updateable list of affected items and a user-updateable list of non-affected items. The list of affected items and the list of non-affected items are created by assigning items that may be affected by a change to one of these lists.

### FIELD OF THE INVENTION

The present invention relates generally to a method and system for managing changes made to items, such as component parts, in a complex, inter-related system, such as an assembled product.

### BACKGROUND

Many manufactured products are assembled from various sub-assemblies and discrete components. Many times, these sub-assemblies and discrete components (“parts”) are themselves developed and manufactured by different supplier companies and are incorporated into many different manufactured end products. For example, a particular automotive vehicle is assembled from many different parts, and those same parts may be used in a variety of other automotive vehicles made by the same manufacturer. Because automotive vehicles (and other assembled products) function as integrated systems, making a change to one part can affect the ability of other parts in the same vehicle to function properly. As a result, a change to one part—such as an engineering design change—may require other parts in the assembled end product (e.g., the vehicle) to be changed to accommodate the original change. Further, a given change to one part can affect each of the vehicles in which it is used in different ways. Accordingly, it is important to be able to analyze and determine the effect that a change to a given sub-assembly or discrete component will have on other parts in the same vehicle, as well as the automotive vehicles themselves in which the changed part is used.

To illustrate a relatively simple exemplary situation that can be addressed by the invention, FIG. 1 sets forth a “tree” diagram of different parts that may be found in a ball point pen. FIG. 1 illustrates three different ball point pen assemblies, i.e., Pen Assembly X, Pen Assembly Y, and Pen Assembly Z, which use some of the same sub-assemblies and discrete components in their manufacture. For example, Pen Assembly X uses: (i) a Front Barrel A, (ii) a Rear Barrel Assembly B, (iii) a Cartridge Assembly F, (iv) a Rear Barrel C, (v) a Button D, (vi) a Clip E, (vii) a Spring H, and (viii) a Ballpoint G. In contrast, Pen Assembly Y uses: (i) a Front Barrel A, (ii) a Rear Barrel Assembly 1, (iii) a Cartridge Assembly F, (iv) a Rear Barrel C, (v) a Clip E, (vi) a Button J; (vii) a Spring H, and (viii) a Ballpoint G. Finally, Pen Assembly Z uses: (i) a Front Barrel K, (ii) a Rear Barrel Assembly I, (iii) a Cartridge Assembly L, (iv) a Rear Barrel C, (v) a Clip E, (vi) a Button J, (vii) a Ballpoint G, and (viii) a Spring M. As can be seen, a change to any one of these parts may affect other parts, and, perhaps, other pen assemblies. For example, if Clip E is changed, Rear Barrel Assembly I may be affected, and, as a result, Pen Assembly Y and Pen Assembly Z may be affected. Further, Rear Barrel C and Button J may be affected. These components may be affected because they somehow use or directly interact with the changed part (e.g., clip E). If any of these sub-assemblies and components are actually affected, then yet other sub-assemblies and components could, in turn, be affected. As can be seen from this simplified example, a change to a single part can result in a complex web of effects, both “upstream” and “downstream” of the changed sub-assembly or component.

In addition to affecting other parts used in the assembly of the end product, changing a given part can affect other things, such as engineering documents, product literature, documentary forms, manufacturing processes, manufacturing plants, supplier companies, etc., which, together with the “parts” used in the assembled end product, are referred to herein as “items.” Moreover, a change to a manufacturing process or at a supplier company may affect product literature or a manufacturing plant. Thus, a change to one item in a system can create complex effects on other various items in the system. Managing and tracking which items are affected by a change to another item is difficult, particularly in systems that are more complicated, and have more items and more “relationships” between the items, than a simple pen assembly.

When a change to a given item is to be made, it is important to analyze all of the possible effects that may occur as a result of the change. In conducting the analysis, it is desirable to be able to efficiently determine which items are definitely affected and which are not affected by a change somewhere else in the system. Heretofore, this process has largely been performed manually, sometimes with the assistance of computer databases that specify “relationships” between various sub-assemblies and components in a product. However, known systems for assisting in the analysis and tracking of effects caused by a change of a given item lack desired functionality for this task, generally only providing the user with a list mechanism for tracking the affected items.

### SUMMARY OF THE INVENTION

A system for managing changes to items associated with a complex system of inter-related items—for example, an assembled product, such as an automobile. The inventive system includes a database having a plurality of records, wherein each record includes information concerning an item associated with the complex system of inter-related items. The information contained in each record includes an identification of other items that could be affected by a change to the item associated with the record. The system further includes a computer-user interface that displays a user-updateable list of affected items, a user-updateable list of items that require additional analysis, and a user-updateable list of non-affected items.

The invented system can be used to more efficiently analyze and manage the effects on various items caused by a change to a given item used in the assembled end product.

### BRIEF DESCRIPTION OF THE DRAWINGS

FIG. 1 is a simplified “tree” illustration of various components and sub-assemblies that could be used in a pen assembly for purposes of illustrating an applicable environment for the invention.

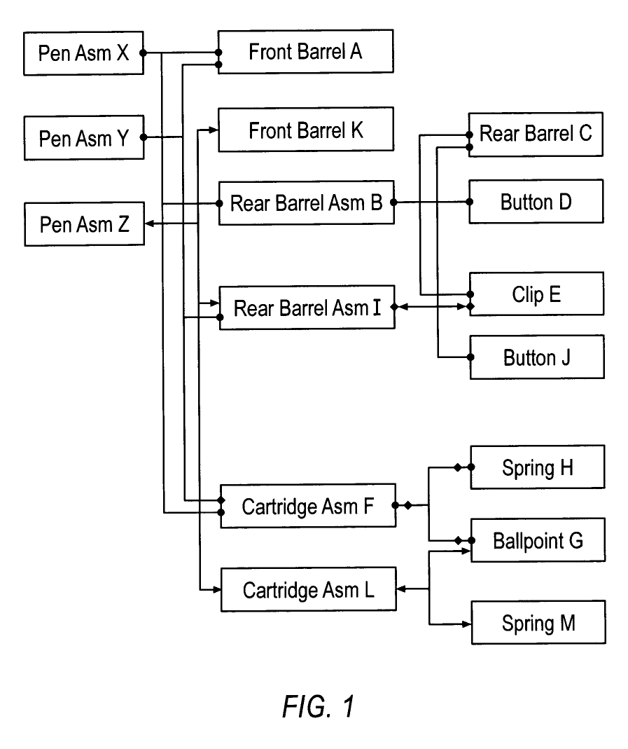

FIG. 2 illustrates an exemplary embodiment of a computer-user interface of the analysis and tracking tool, according to the present invention.

FIG. 3 is a flow chart that illustrates an exemplary method of analyzing and tracking changes in a system, including an exemplary method of using the analysis and tracking tool, according to the invention.

### DETAILED DESCRIPTION

The present invention is hereinafter described in the context of one particular embodiment. It should be noted that one of skill in the art will recognize that modifications to the disclosed embodiment could be made and still remain within the scope and spirit of the invention. Moreover, while the described embodiment involves the management of changes made to items associated with an assembled product, the inventive system also can be used in connection with a variety of complex systems of inter-related items, some of which that do not involve an assembled end product.

The invention relates to a tool for analyzing, tracking and managing affected and non-affected items resulting from a change made to a “changed item” in the complex system of inter-related items such as an assembled end product. The invention also relates to a method of using the tool.

At the outset, the inventive analysis and tracking tool will be described. The analysis and tracking tool includes a database and a computer-user interface to the database. The database may contain a record for each item associated with the end product, including each part that makes up the end product and any other items associated with the end product, such as engineering drawings, customer documentation, supplier companies, etc. For example, in the case of an automotive vehicle, the database could include a record for each part that goes into a particular completed automotive vehicle, as well as other associated items. Each record includes searchable item identifiers (such as a part number) and information that relates the given item with other items associated with the assembly of the vehicle. For example, a record in the database for the windshield of a particular vehicle may be “related” to a record for a windshield seal, a record for the vehicle hood, a record for the vehicle roof, a record for the vehicle doors, and several other records for items that may be affected if the windshield on the vehicle were to be changed. The records of the database should be logically associated such that it is possible to query the database for a particular item identifier (such as a part number), and, in response, return all parts and other items in the end product that are “related”—i.e., could be affected by a change of the given item. Further, the database could include “relationships” between the various items and other end products in which the items are used. For instance, if the particular automotive windshield described above were used in several different vehicles made by the same manufacturer, then the windshield may be logically associated with sub-assemblies and components in each of the vehicles in which the windshield is used. The database can be implemented through a variety of commercially-available database programs, such as, for example, Microsoft Access.®

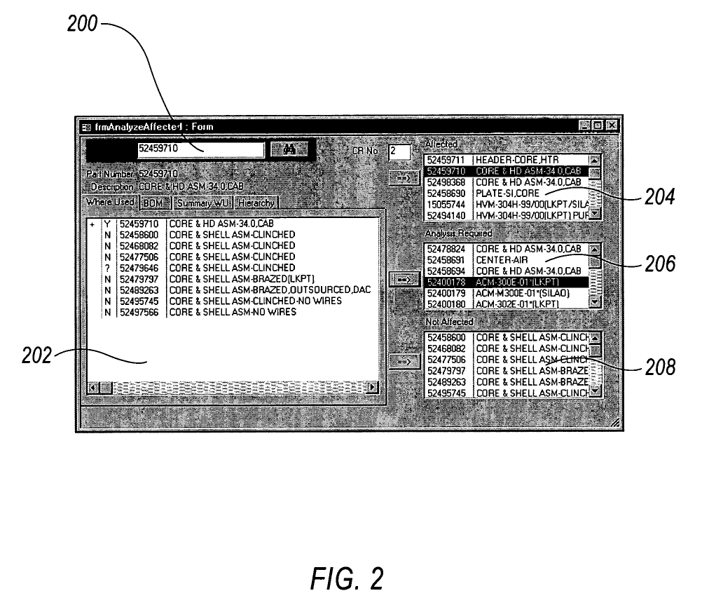

The user interface portion of the analysis and tracking system is configured to display information to a human user concerning relationships between a changed item and the various items that may or may not, as a result, be affected by the change. FIG. 2 illustrates an exemplary user interface that could be implemented in connection with the present invention. As illustrated in FIG. 2, the analysis and tracking interface may include an input field 200 where a human operator may input an item identifier, such as a part number or a document number, for example. The user interface also includes a “related items” list 202, where a list of items can be displayed in response to the item identifier input in the input field 200. In operation, a human user inputs an item identifier (e.g., a part number) into the input field 200, representing the “changed item.” The database retrieves all items that are “related” to the changed item and displays those related items in the “related items” list 202. In this way, the human user of the tool can easily view each item that may be affected by a change to the item in question (the “changed item”). As illustrated in FIG. 2, Part Number 52486367 is shown as being the changed item. Those items that are “related” to Part Number 5248637 are displayed in the “related items” display area 202. The list of related items may be filtered and sorted by many attributes, including the type of relationship between the item input in field 200 and the related items.

The user interface also includes an “affected” list 204, an “analysis required” list 206, and a “not affected” list 208. These three lists 204, 206, 208 are used by the system and by the human user to categorize the related items displayed in the “related items” list 202. That is, each related item that appears in the “related items” list 202 will ultimately be assigned to one of the three categories of “affected”, “analysis required” or “not affected.” The related items are categorized either automatically by the system (via computer software) pursuant to established “rules” or manually by the human user. More specifically, when a part identifier (e.g., part number) is input into the input field 200, the database displays all related items in the “related items” list 202. The system can be programmed with established categorization “rules” such that when an item is placed into one of the three categories (“affected”, “analysis required” or “not affected”), some of the related items, depending on their specific natures, may be automatically categorized as “affected”, “analysis required”, or “not affected.” For example, following is a list of exemplary rules that could be built into the system to automatically categorize some “related items”:

1. Any item that uses an “affected” item, if not already categorized as “affected” or “not affected”, is categorized as “analysis required.”

2. Any manufacturing facility that produces an “affected” item is categorized as “affected.”

3. Any customer for an “affected” saleable product is categorized as “affected.”

4. Any supplier for an “affected” item is categorized as “affected.”

5. Specific documents (e.g., CAD models, engineering drawings, cost estimates, etc.) that describe an “affected” item are categorized as “affected”, or “analysis required.”

For those related items that are not automatically categorized by the system pursuant to established “rules”, the human operator must use his/her own analytical skills to manually evaluate the nature of each related item and determine into which of the three categories each related item should be assigned. That is, upon reviewing the “related items” list 202, the human operator may be able to determine immediately that certain of the related items will definitely not be affected by the proposed change to the “changed item”, and those parts would be assigned to “not affected” list 204 by the human user. The human user may be able to immediately determine that certain of the “related items” will definitely be affected by the proposed change to the “changed part”, and those items would be assigned to the “affected” list 206 by the human user. Finally, for some of the “related items”, the human user may not be able to immediately or easily determine whether they are “affected” or “not affected.” For such parts, the human user can assign these items to the “analysis required” list 208, which is a running list of those items that must be evaluated further. The “related parts” can be placed on one of the “affected”, “analysis required”, or “not affected” lists using a variety of computer techniques, including, for example, by using the computer mouse to simply “click” on the related item(s) and “click” a button to move the items to one of the three lists, or “drag and drop” the related item(s) to one of the three lists.

As illustrated in FIG. 2, once a “related item” is assigned to one of the “affected”, “analysis required” or “not affected” lists, a visual indicator automatically marks the “related item” in the “related items” list 202. For example, in FIG. 2, those “related items” that have been placed on the “affected” list 204 are toggled in the “related items” list 202 with a “Y”; those “related items” that have been placed on the “analysis required” list 206 are toggled in the “related items” list 202 with a “?”; and those “related items” that have been placed on the “not affected” list 208 are toggled in the “related items” list 202 with an “N”. Items with no visual indicator mark have not yet received any analysis by the human user.

It should be recognized that once it is determined that a particular “related item” is “affected”, that means that the “related item” will itself require some sort of change or re-design to accommodate the originally-contemplated change to the “changed item.” For instance, an affected part may need to be re-engineered, and an affected document may require portions to be re-written. A change to an “affected” item may result in additional changes to yet other items in the end product to accommodate the change. For example, in the automotive windshield example described above, if it is determined that a change to the shape of the windshield requires a change to the shape of the vehicle hood, the required change to the vehicle hood may then result in required changes to other items, such as the hinges used to secure the hood to the vehicle. In essence, any item that is “affected”, may, in turn, affect other items in the end product. It is desirable to track and manage these “downstream” affects. Accordingly, for any item that is placed on the “affected” list 204 (either automatically pursuant to established rules or manually by the human user), the items that are related to the “affected” items are also displayed in the “related items” list 202. These new additions to the “related items” list 202 are handled in the same way as described above. That is, some of the new “related items” may be automatically categorized as “affected”, “analysis required” or “not affected” pursuant to established “rules”, and the remaining “related items” will be manually categorized by the human user as described above.

The analysis and tracking tool (i.e., database and interface) provides a convenient way for a human user to organize, manage and track those items in an end product affected by a change to a given item. Moreover, the analysis and tracking tool provides a way for the human user to track those items which are not affected, or which may require additional analysis before definitively determining whether they are affected or not. The inclusion of the “not affected” category is particularly useful for reducing or eliminating duplicative analysis by the human user of items for which it has previously been determined that the proposed change would have no effect. Further, the “analysis required” category is useful for maintaining a list of those items for which the human user must acquire additional information before making a determination.

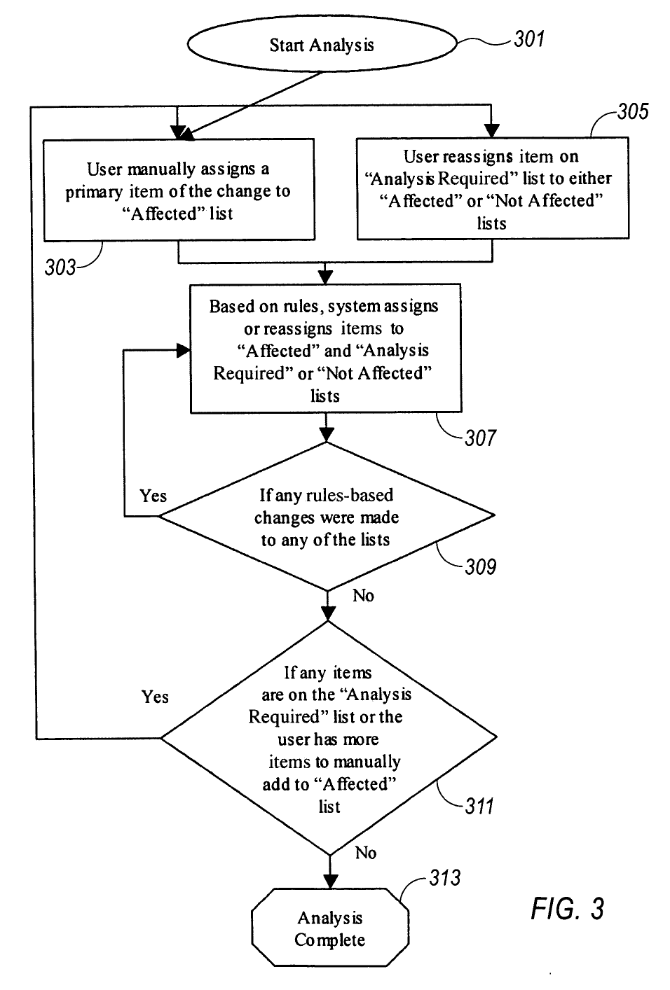

Now, operation and use of the analysis and tracking tool described above will be discussed in more detail. FIG. 3 sets forth a flow chart illustrating an exemplary method for using the analysis and tracking tool. Use of the tool starts at step 301, wherein the analysis is started. At the beginning of the analysis, the human user has in mind an item from the end product that is to be changed. The human user inputs the “changed item” into the input field 200 (in FIG. 2). This item can either be input manually, or be automatically entered if a user selects an item from one of the lists (202, 204, 206, or 208) and commands the system to input it into the input field 200 using a variety of computer techniques, including, for example, by using the computer mouse to simply “double click” on the item, or to “drag and drop” the item into the input field 200.

In response, the database returns a list of “related items” in the “related items” list 202. At step 303, the human user assigns the “changed item” to the “affected” list 204. Then, at step 307, the system automatically applies any established automatic “rules” to the “related items” list 202. As a result of the “changed item” being placed on the “affected” list 204, the established “rules” may call for certain of the items on the “related items” list 202 to be automatically assigned to one of the “affected”, “analysis required” or “not affected” lists, in which case, the system will automatically make those assignments. At step 309, the system determines if any updates were made to any of the “affected”, “analysis required” or “not affected” lists, based upon the established “rules.” If so, then additional “automatic” assignments may need to be made pursuant to the established rules, and, therefore, step 307 is repeated. Step 307 is repeated until all of the rules-based automatic updates to the lists have been made.

Thereafter, at step 311, the human user reviews the computer-user interface to determine if (i) there are any items on the “related items” list 202 that have not been assigned to either the “affected”, “analysis required”, or “not affected” lists, or (ii) there are any items that remain on the “analysis required” list 206. If either of these conditions is true, then the human user performs either step 303 or 305, depending upon which condition is true. Specifically, if there remains items on the “related items” list 202 that have not been assigned to either the “affected”, “analysis required”, or “not affected” list, then the user, at step 303, will assign one of the remaining unassigned “related items” to one of the “affected”, “analysis required”, or “not affected” lists. Optionally, the human user can choose not to assign an item from the “related items” list to the “not affected” list if it is not affected. However, the human user loses the benefit of having the item on the “not affected” list, which could reduce their redundant analysis of said item, if it would later appear in the “related items” list 202 during the analysis. If there are items that remain in the “analysis required” list 206, then the human user, at step 305, may re-assign one of the items on the “analysis required” list 206 either to the “affected” list 204 or the “not affected” list 208.

This algorithm is repeated by the human user and the system until, at step 311, it is determined both that (i) all items on the “related items” list 202 have been assigned to one of the “affected”, “analysis required”, or “not affected” lists; and (ii) all items on the “analysis required” list 204 have been assigned to either the “affected” list 204 or the “not affected” list 208. In effect, when all of the “related items” have been considered by the human user (or the system) and assigned either to the “affected” list or the “not affected” list, then the analysis is complete. At this point, the human user will have a complete list of all of the items that will be affected by the original changed item, as well as a complete list of those related items that have been considered and determined not to be affected.

In the normal course of performing the above-described analysis, a user may want to change one of his/her earlier categorizations of an item as “affected”, “needs analysis”, or “not affected.” For example, a user may decide later in the analysis that an item previously categorized as “not affected” should actually be categorized in the “affected” list. One way to do this would be to manually move the item in question from the “not affected” list to the “affected” list. However, this method of changing an earlier categorization decision should be done rarely, if at all, because categorization decisions made earlier in the analysis affect the overall direction of the analysis. If such a manual change is made to an earlier categorization decision, it is possible that the overall integrity of the analysis could be compromised because subsequent categorization decisions (either manual or automatic) may no longer be valid. Therefore, to minimize this problem, it is preferable to include an “undo” function in the system. Specifically, the system may include the ability to allow a user to “undo” previous assignments made to one of the “affected”, “analysis required” and “not affected” lists. The “undo” function allows the human user to change one of his/her previous decisions without having to re-start the analysis from the beginning. In the event that the human user performs an “undo” function, all assignments made (either manually or automatically) that depend in some way on the “undone” assignment would also be automatically “undone” in order to maintain the integrity of the overall analysis. Specifically, items that were originally modified (placed on one of the three lists) due to an “undone” categorization could be reverted, or, at the option of the user, be placed on the “needs analysis” list. The “undo” function should be reiterative in the sense that a user could “back up” through multiple levels of the analysis without compromising the integrity of the analysis.

The described embodiment of the invention is beneficial because it allows a human user to easily keep track of related items that are affected by a proposed change to another item in the end product. Moreover, the described embodiment allows a human user to easily track those related items that have already been considered and determined not to be affected by the proposed change, as well as those items that require additional analysis before a determination can be made. Further, the described embodiment provides an easily-observable indication on the “related items” list 202, which identifies those related items that have already been assigned to one of the “affected”, “analysis required” or “not affected” lists.

While the present invention has been particularly shown and described with reference to the foregoing preferred and alternative embodiments, those skilled in the art will understand that many variations may be made therein without departing from the spirit and scope of the invention as defined in the following claims. Accordingly, this description of the invention should be understood to include all novel and non-obvious combinations of elements described herein, and claims may be presented in this or a later application to any novel and non-obvious combination of these elements. The foregoing embodiments are illustrative, and no single feature or element is essential to all possible combinations that may be claimed in this or a later application. Where the claims recite “a” or “a first” element of the equivalent thereof, such claims should be understood to include incorporation of one or more such elements, neither requiring nor excluding two or more such elements. Further, the use of the words “first”, “second”, and the like do not alone imply any temporal order to the elements identified. The invention is limited only by the following claims.

1. A system for managing a change to an item associated with a complex system of inter-related items comprising:
a database comprising a plurality of records, wherein each record includes information concerning an item associated with the complex system, said information including an identification of other items that could be affected by a change to the changed item; and
a computer-user interface displaying a user-updateable list of affected items and a user-updateable list of non-affected items.

2. The system of claim 1, wherein said computer-user interface further includes a user-updateable list of items that require additional analysis before said items can be assigned to either said affected items list or said non-affected items list.

3. The system of claim 2, further including one or more predetermined rules used by the system to automatically assign one or more of said items that could be affected to one of (i) said list of affected items, (ii) said list of items that require additional analysis, and (iii) said list of non-affected items.

4. The system of claim 1, wherein said items include parts used in an assembled end product and documents associated with said assembled end product.

5. The system of claim 1, wherein said computer-user interface further includes a user-updateable input field for receiving an identifier of said item to be changed; and a list of related items that could be affected by a change made to said item to be changed.

6. The system of claim 5, wherein said list of related items is generated automatically in response to a query to said database based upon said identifier of said changed item in said input field.

7. The system of claim 5, wherein said computer-user interface further includes one or more visual indicators associated with said items on said related items list that indicate if said related items are assigned to said list of affected items, said list of items that require additional analysis, and said list of non-affected items.

8. The system of claim 1, further including one or more predetermined rules used by the system to automatically assign one or more of said items that could be affected to one of said list of affected items, said list of items that require additional analysis, and said list of non-affected items.

9. The system of claim 1, further including an “undo” function that allows a human user of the system to retract a previous assignment of an item to either said list of affected items or said list of non-affected items.

10. The system of claim 9, wherein said “undo” function includes reversing any assignments of items made to said list of affected items or said list of non-affected items that were influenced by the assignment of said retracted item.

11. A method of managing changes to items associated with a complex system of inter-related items comprising:
searching a database for items related to a changed item;
assigning each of said related items to (i) an affected items list, (ii) a non-affected items list, and (iii) an analysis required list, depending upon whether each of the related items (i) is affected by a change to said changed item, (ii) is not affected by a change to said changed item, and (iii) requires additional analysis to determine if the related item is affected or not affected; and
wherein said affected items list, said non-affected items list, and said analysis required list, are incorporated into a computer-user interface.

12. The method of claim 11, wherein a human user manually assigns at least some of said related items to said affected items list, said non-affected items list, and said analysis required list; and wherein at least some of said related items are automatically assigned to said affected items list, said non-affected items list, and said analysis required list by pre-established rules applied by computer software.

13. The method of claim 11, further including the steps:
generating a list of related items on said computer-user interface in response to said database search; and
providing a visual indication associated with each of said related items that indicates if said related item has been assigned to said affected list, said non-affected list, and said analysis required list.

14. The method of claim 11, further including the steps:
analyzing items assigned to said analysis required list to determine if said analysis required items would be affected by a change to said changed item; and
assigning said analysis required items to said affected items list and said non-affected items list, depending upon whether or not said analysis required items would be affected by a change to said changed item.

15. The method of claim 14, wherein said step of assigning said analysis required items is performed manually by a human user.

16. The method of claim 14, wherein one or more of said searching, said analyzing, and said assigning steps are repeated until no items remain on said analysis required list.

17. A system for managing a change to an item associated with an assembled end product, comprising:
a database comprising a plurality of records, wherein each record includes information concerning an item associated with the assembled end product, said information including an identification of other items that could be affected by a change in said associated item;
a computer-user interface configured to display a user-updateable list of affected items, a user-updateable list of non-affected items, and a user-updateable list of items requiring additional analysis;
wherein said computer-user interface further includes a list of related items that could be affected by a change to the changed item, said related items list being automatically generated in response to a query of said database; and
wherein said computer-user interface is configured to permit a human user to manually assign items on said related items to said affected items list, said non-affected items list, and said analysis required list.

18. The system of claim 17, further comprising software that automatically assigns at least some of said related items to said affected items list, said non-affected items list, and said analysis required list based upon pre-determined rules.

19. The system of claim 17, further comprising a means for providing a visual indication associated with said related items list on said user-computer interface that indicates whether said items on said related items list have been assigned to said affected items list, said non-affected items list, or said analysis required list.

20. The system of claim 17, further comprising an “undo” function that de-assigns a previously assigned item from said affected items list, said non-affected items list, and said analysis required list.

21. The system of claim 20, wherein said “undo” function includes reversing any assignments of items made to said list of affected items or said list of non-affected items that were influenced by the assignment of said retracted item.
